(19) United States
(12) Patent Application Publication
(10) Pub. No.: US 2024/0122012 A1
(43) Pub. Date: Apr. 11, 2024

(54) DISPLAY DEVICE

(71) Applicant: Japan Display Inc., Tokyo (JP)

(72) Inventors: Kazuyuki HARADA, Tokyo (JP); Hideyuki TAKAHASHI, Tokyo (JP); Hiroshi TABATAKE, Tokyo (JP); Masato NAKAMURA, Tokyo (JP)

(73) Assignee: Japan Display Inc., Tokyo (JP)

(21) Appl. No.: 18/476,353

(22) Filed: Sep. 28, 2023

(30) Foreign Application Priority Data
Oct. 7, 2022 (JP) 2022-162743

(51) Int. Cl. H10K 59/131; G06F 3/041; G06F 3/044; H10K 59/40

(52) U.S. Cl. CPC H10K 59/131; G06F 3/0412; G06F 3/04164; G06F 3/0446; H10K 59/40

(57) ABSTRACT

A display device includes a display region on a substrate, a first step portion surrounding the display region in a plan view, a first sensor electrode in the display region, a first sensor wiring electrically connected with the first sensor electrode, a first terminal electrode located between the display region and an edge of the substrate, a first terminal wiring electrically connected to the first terminal electrode, at least one contact hole located between the first step portion and the first terminal electrode, at least one first insulating layer located around a periphery of the at least one contact hole, a second insulating layer between the at least one first insulating layer and the substrate in a cross section, and a third insulating layer over the first insulating layer and the second insulating layer.

### CROSS-REFERENCE TO RELATED APPLICATION

This application claims the benefit of priority to Japanese Patent Application No. 2022-162743 filed on Oct. 7, 2022, the entire contents of which are incorporated herein by reference.

### FIELD

An embodiment of present invention relates to a display device.

### BACKGROUND

As one type of display device to which a flexible printed substrate is bonded, a display device employing an on-cell type touch sensor is known (see Japanese Laid-Open Patent Publication No. 2019-74709). An electrode used for the touch sensor is formed on a sealing layer of the touch sensor, and a wiring for transmitting a signal from the electrode to the flexible printed substrate is formed on the display device.

After forming the wiring for transmitting the signal from the electrode used for the touch sensor to the flexible printed substrate, a process of covering the touch sensor and an entire peripheral region with an overcoat layer is performed. In this case, the overcoat layer is repelled at a contact portion where the wiring of the electrode used for the touch sensor is taken into a mounting wiring portion, so that the overcoat layer cannot sufficiently cover the contact portion.

Heretofore, although a condition of a process of forming the overcoat layer, for example, a condition such as coating speed and coating film thickness of the overcoat layer, is changed to attempt to improve the coating state of the overcoat layer with respect to the contact portion, it is not possible to stably supply the overcoat layer having a good coating state.

### SUMMARY

A display device according to an embodiment of the present invention includes a display region on a substrate, a first step portion surrounding the display region in a plan view, a first sensor electrode in the display region, a first sensor wiring electrically connected with the first sensor electrode, a first terminal electrode located between the display region and an edge of the substrate, a first terminal wiring electrically connected to the first terminal electrode, at least one contact hole located between the first step portion and the first terminal electrode, at least one first insulating layer located around a periphery of the at least one contact hole, a second insulating layer between the at least one first insulating layer and the substrate in a cross section, and a third insulating layer over the first insulating layer and the second insulating layer, wherein the first sensor wiring and the first terminal wiring are electrically connected through the at least one contact hole, the first sensor wiring is arranged over the first terminal wiring and the third insulating layer in a cross section, the first sensor wiring includes a first edge and a second edge with different heights from the substrate over the third insulating layer, the first edge is located on a part of the third insulating layer in contact with the at least the first insulating layer, and the second edge is located over a part of the third insulating layer in contact with the second insulation layer.

### BRIEF DESCRIPTION OF DRAWINGS

FIG. 1 is a schematic top view of a display device according to an embodiment of the present disclosure.

FIG. 2 is a schematic top view of a display device according to an embodiment of the present disclosure.

FIG. 3 is a circuit diagram of a pixel of a display device according to an embodiment of the present disclosure.

FIG. 4 is a schematic end view of a display device according to an embodiment of the present disclosure.

FIG. 5 is a schematic top view of a display device according to an embodiment of the present disclosure.

FIG. 6 is a schematic top view of a display device according to an embodiment of the present disclosure.

FIG. 7 is a schematic end view of a display device according to an embodiment of the present disclosure.

FIG. 8 is a schematic end view of a display device according to an embodiment of the present disclosure.

FIG. 9 is a schematic end view of a display device according to an embodiment of the present disclosure.

FIG. 10A is a schematic top view of a display device according to a comparative example.

FIG. 10B is a schematic end view of a display device according to a comparative example.

FIG. 11A is a schematic top view of a display device according to an embodiment of the present disclosure.

FIG. 11B is a schematic end view of a display device according to an embodiment of the present disclosure.

FIG. 12 is a schematic end view of a display device according to an embodiment of the present disclosure.

FIG. 13 is a schematic top view of a display device according to an embodiment of the present disclosure.

FIG. 14 is a schematic top view of a display device according to an embodiment of the present disclosure.

FIG. 15 is a schematic top view of a display device according to an embodiment of the present disclosure.

FIG. 16 is a schematic top view of a display device according to an embodiment of the present disclosure.

FIG. 17 is a schematic top view of a display device according to an embodiment of the present disclosure.

FIG. 18 is a schematic top view of a display device according to an embodiment of the present disclosure.

### DESCRIPTION OF EMBODIMENTS

Hereinafter, each of the embodiments of the present invention will be described with reference to the drawings and the like. However, the present invention can be implemented in various aspects without departing from a gist thereof, and is not to be construed as being limited to the descriptions of the embodiments exemplified below.

In the drawings, although widths, thicknesses, shapes, and the like of respective portions may be schematically represented in comparison with actual embodiments for clarity of explanation, the drawings are merely examples, and do not limit the interpretation of the present invention. In the present specification and the drawings, elements having the same functions as those described with respect to the drawings described above are denoted by the same reference symbols, and duplicate descriptions thereof may be omitted.

In this specification and claims, in the case of expressing a manner of placing another structure on a certain structure, the term “over/on” shall include both placing another structure directly on a certain structure and placing another structure over a certain structure via yet another structure, unless otherwise specified.

In this specification and claims, the phrase “a structure is exposed from another structure” means an aspect in which a part of the structure is not covered by another structure, and this part not covered by the other structure includes an aspect covered by yet another structure.

In the present specification and claims, the term end view refers to a vertical cut of an object as viewed from a side. The end view shall include the view as viewed from the end. The expression planar view indicates when the object is viewed from directly above. Top view or plan view shall contain a diagram of a planar view.

### First Embodiment

### 1. Overall Structure

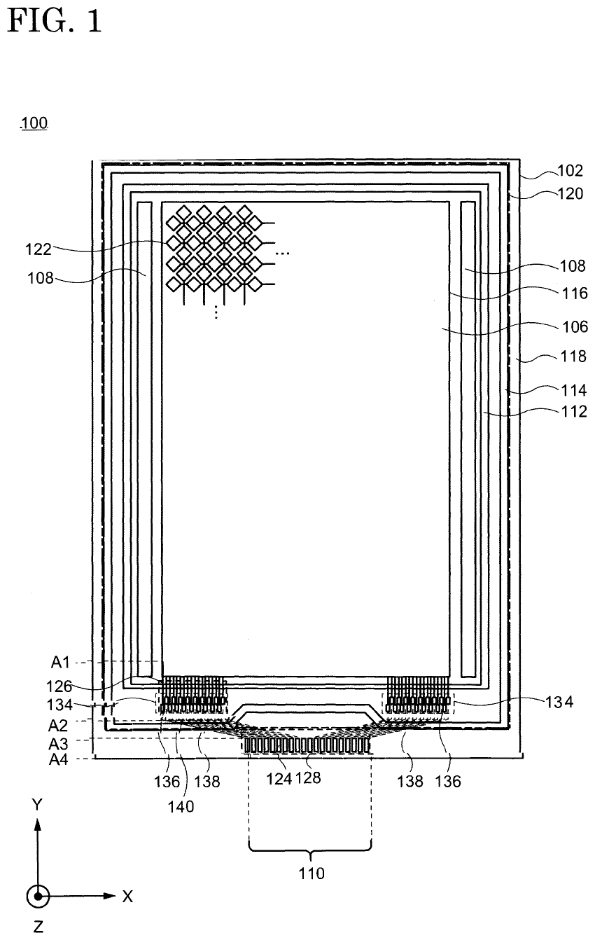

In the present embodiment, a configuration of a display device 100 according to an embodiment will be described. FIG. 1 is a schematic top view of a display device according to an embodiment.

As shown in FIG. 1, the display device 100 has a substrate 102, a display region 116, a touch sensor 106, a sensor electrode 122, a sensor wiring 126, a contact portion 134, a contact hole 136, a terminal wiring 138, a mounting pad 110, a terminal electrode 124, a COF installation region 128, a driving circuit 108, a first step portion 112, and a second step portion 114 arranged on the substrate 102.

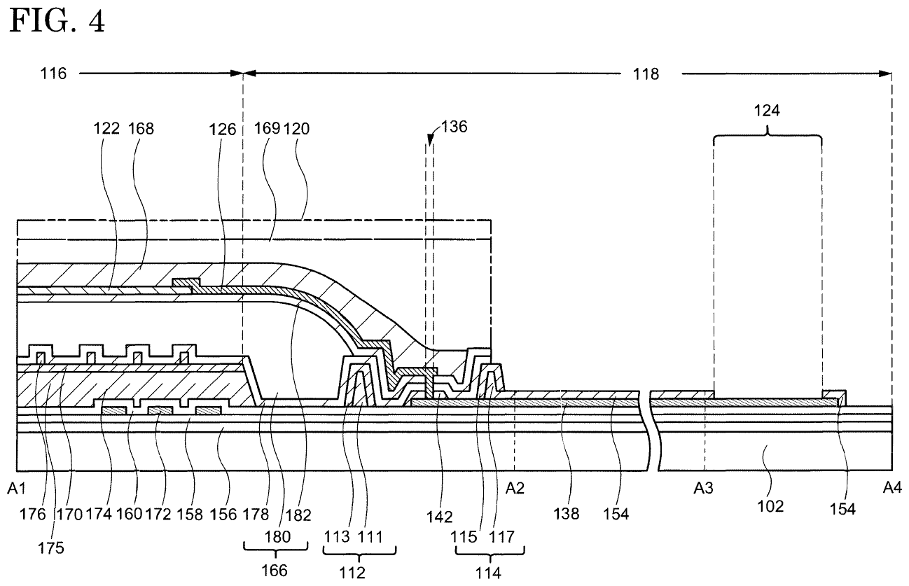

The display device 100 comprises the display region 116 and a peripheral region 118 surrounding the display region 116. The touch sensor 106 is arranged in the display region 116. In the peripheral region 118, the driving circuit 108, the mounting pad 110, the contact portion 134, the contact hole 136, the first step portion 112, and the second step portion 114 are arranged. Although omitted in FIG. 1, the display device 100 further includes a counter substrate 120 paired with the substrate 102, so as to overlap the display region 116 and the peripheral region 118 as shown by the dotted lines in FIG. 4 which will be described later.

The touch sensor 106 is arranged with the sensor electrode 122. The sensor electrode 122 is directly or electrically connected to the sensor wiring 126. The sensor wiring 126 is electrically connected to the terminal wiring 138 via the contact hole 136 arranged in the contact portion 134. The terminal wiring 138 is directly or electrically connected to the terminal electrode 124 arranged in the mounting pad 110. As a result, the sensor electrode 122 is electrically connected to the terminal electrode 124. The sensor electrode 122 and the terminal electrode 124 should be electrically connected to each other, and the sensor electrode 122 and the terminal electrode 124 may be electrically connected to each other via a plurality of wirings.

An outline of the substrate 102 may be rectangular or polygonal as shown in FIG. 1. Further, the outline of the substrate 102 may have an arcuate portion. Here, in the case where a plurality of display devices 100 is manufactured from one substrate, an outline of the display device 100 cut out from the one substrate is used as the outline of the substrate 102.

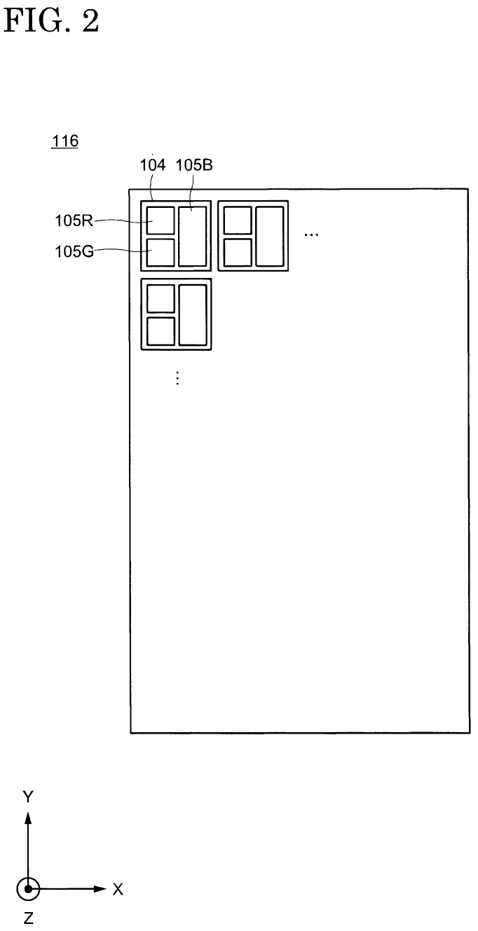

The display region 116 may further include a plurality of pixels. FIG. 2 shows a schematic plan view of the display region 116. FIG. 2 shows a plan view of layers in which a plurality of pixels 104 is arranged. As shown in FIG. 2, the plurality of pixels 104 is arranged in the display region 116 in, for example, a row direction (X direction) and a column direction (Y direction). The pixels 104 may be arranged with a plurality of light emitting elements 105, for example, a light emitting element 105R, a light emitting element 105G, and a light emitting element 105B. Each of the light emitting element 105R, the light emitting element 105G, and the light emitting element 105B may emit light of a different color. For example, the light emitting element 105R may emit red, the light emitting element 105G may emit green, and the light emitting element 105B may emit blue. The light emitting element 105 may be arranged with, for example, an organic electroluminescent (EL) device.

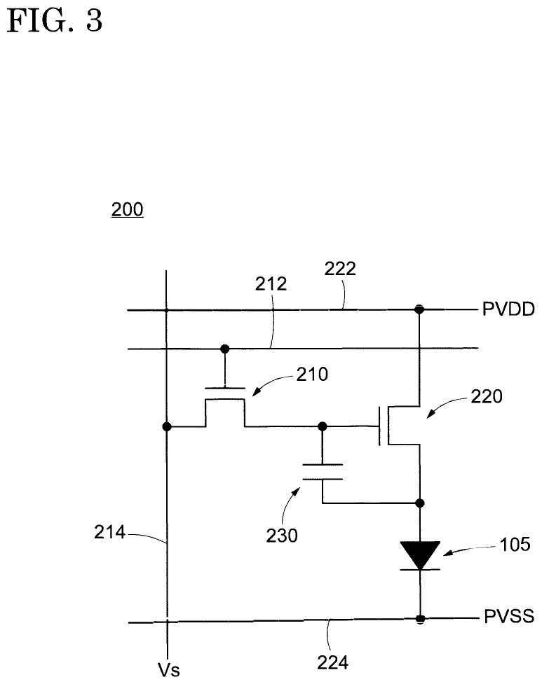

The light emitting element 105 is electrically connected to transistors arranged in the respective pixels 104. FIG. 3 is a circuit diagram showing a circuit configuration of the pixel 104. A pixel circuit 200 of the pixel 104 includes a selection transistor 210, a drive transistor 220, a capacitor 230, and the light emitting element 105.

The selection transistor 210 is connected to a gate line 212 and a data line 214. Specifically, the gate line 212 is connected to a gate of the selection transistor 210. The data line 214 is connected to a source of the selection transistor 210. The selection transistor 210 functions as a switch for selecting whether a data signal (video signal Vs) is input to the pixel circuit 200. A drain of the selection transistor 210 is connected to a gate of the drive transistor 220 and the capacitor 230.

The drive transistor 220 is connected to an anode power supply line 222, the light emitting element 105 and the capacitor 230. Specifically, the anode power supply line 222 is connected to the drain of the drive transistor 220. The light emitting element 105 is connected to the drive transistor 220. The capacitor 230 is connected between the gate and a source of the drive transistor 220. The drive transistor 220 controls the amount of current flowing through the light emitting element 105. A high potential power supply line (PVDD) is applied to the anode power supply line 222.

The capacitor 230 holds the data signal input through the selection transistor 210. A voltage corresponding to the data signal held in the capacitor 230 is applied to the gate of the drive transistor 220. Accordingly, the amount of current flowing through the drive transistor 220 is controlled in accordance with the data signal.

The light emitting element 105 is connected between the drive transistor 220 and a cathode power supply line 224. Specifically, an anode of the light emitting element 105 is connected to the source of the drive transistor 220. That is, the anode of light emitting element 105 is connected to the anode power supply line 222 via the drive transistor 220. A cathode of the light emitting element 105 is connected to the cathode power supply line 224. A low potential power source (PVSS) is applied to the cathode power supply line 224.

In the pixel circuit 200, when selection transistor 210 is turned on, the data line 214 receives the data signal. The voltage corresponding to the input data signal is held by the capacitor 230. Thereafter, in a light emission period, the gate of the drive transistor 220 is controlled by the voltage held in the capacitor 230, and the current corresponding to the data signal flows through the drive transistor 220. When the current flows through the light emitting element 105, the light emitting element 105 emits light with a brightness corresponding to the current.

The signal supplied to the pixel circuit 200 is supplied from the driving circuit 108 electrically connected to the pixel circuit 200. The driving circuit 108 may be arranged between the display region 116 and the first step portion 112. Although FIG. 1 shows an exemplary arrangement in which a plurality of driving circuits 108 sandwiches the display region 116, the arrangement is not limited to this.

The driving circuit 108 may be electrically connected to an external driving circuit via a wiring (not shown), and may drive the pixel 104 in response to a signal supplied from the external driving circuit. As the external driving circuit, a driving IC (Integrated Circuit) can be used. The driving IC can supply a signal to the driving circuit 108 via the mounting pad 110.

The driving IC may be mounted on the substrate 102 by, for example, COF (Chip On Film) using anisotropic conductive films (ACF). In this case, for example, FOG (Film On Glass) on which a wiring substrate is mounted using the anisotropic conductive film can be used as the terminal electrode 124 of the mounting pad 110. In the case where COF is installed in the mounting pad 110 using FOG, COF is installed by thermocompression bonding with the mounting pad 110 in the COF installation region 128 including the mounting pad 110 shown in FIG. 1.

As described above, since the mounting pad 110 is used to connect to the external driving circuit, it is arranged at a region close to an end portion of the substrate 102. Specifically, as shown in FIG. 1, the mounting pad 110 is arranged between the end portion of the substrate 102 and the second step portion 114.

As shown in FIG. 1, the touch sensor 106 may include a plurality of sensor electrodes 122. Although the sensor electrode 122 is shown in FIG. 1 as a diamond shape having diagonal lines in the directions X and Y, the shape is not limited to this. The plurality of sensor electrodes 122 is arranged in the display region 116 so as to overlap the pixels 104. In other words, the plurality of sensor electrodes 122 is arranged so as to overlap at least a part of the pixel 104 (a part of a light emitting element arranged in a pixel). With this arrangement, the presence or absence of a touch can be sensed by the touch sensor 106 while an image such as an icon is displayed on the pixel 104.

As the touch sensor 106, a capacitive method, a resistance film method, or the like can be used. In the case where the capacitive type is used for the touch sensor 106, the plurality of sensor electrodes 122 is arranged in a matrix in the display region 116, for example. The plurality of sensor electrodes 122 may be connected in the row direction (direction X) or the column direction (direction Y), respectively, as shown in FIG. 1. The sensor electrode 122 connected in the row direction and sensor electrode 122 connected in the column direction are spaced apart from each other. The sensor electrode 122 connected in the row direction or the column direction may function as an electrode for transmitting or receiving, respectively. Further, the sensor electrode 122 connected in the row direction or the column direction is electrically connected to the external driving circuit. One of the sensor electrodes 122 connected in the row direction or the column direction may be arranged with a signal from an external driving circuit and the other may be arranged with a signal to an external driving circuit.

As a driving circuit for the driving sensor electrode 122, the driving IC can be used as in the external driving circuit of the pixel 104. The sensor electrode 122 is electrically connected to the driving IC via the mounting pad 110 which is electrically connected to the sensor wiring 126. FOG or COF described above can be used for the mounting pad 110 and the driving IC.

As shown in FIG. 1, the sensor wiring 126 and terminal wiring 138 are directly or electrically connected to each other in the contact holes 136 so that the sensor wiring 126 and the mounting pad 110 are electrically connected to each other. Further, the terminal wiring 138 is directly or electrically connected to the mounting pad 110.

The sensor wiring 126 is arranged from one side of the sensor electrodes 122 connected in the row direction or the column direction, respectively, as shown in FIG. 1. As shown in FIG. 1, the sensor wiring 126 is directly or electrically connected to the terminal wiring 138 in the contact hole 136. A plurality of contact holes 136 is included in the contact portion 134.

The contact portion 134 is arranged between the first step portion 112 surrounding the display region 116 and the second step portion 114 surrounding the first step portion 112. The contact portion 134 is located between the end portion of the substrate 102 on which the mounting pad 110 is arranged and the first step portion 112. FIG. 1 shows an example in which a plurality of contact portions 134 is arranged. In the case where the plurality of contact portions 134 is arranged, the plurality of contact portions 134 can be arranged on both sides of a region between the mounting pad 110 and the display region 116 as shown in FIG. 1. In this case, the second step portion 114 may be shaped to protrude toward the display region 116 from the end of the substrate 102 in the region where the mounting pad 110 and the display region 116 sandwich.

The sensor wiring 126 electrically connected to the contact portion 134 extends across the first step portion 112 between the sensor electrode 122 and the contact portion 134. Further, the terminal wiring 138 electrically connected to the contact portion 134 extends across the second step portion 114 between the mounting pad 110 and the contact portion 134.

### 2. Partial Structure

### 2-1. Cross-Sectional Structure

FIG. 4 shows a schematic end view along a dashed line A1-A4 shown in FIG. 1. Hereinafter, the same configurations as those in FIG. 1 to FIG. 3 will be omitted in some cases.

The display device 100 includes the substrate 102, and the substrate 102 may be made of, for example, a glass and quartz substrate, or an organic resin substrate. In the case where the organic resin substrate is used, the substrate 102 may have flexibility.

A base film 156 may be arranged over the substrate 102. The base film 156 can prevent contamination from the substrate 102, and can use, for example, an inorganic insulating material. As the inorganic insulating material, for example, silicon nitride, silicon oxide, and composites thereof can be used.

An insulating film 158 may be arranged over the base film 156. The insulating film 158 in the display region 116 may have a function of a gate insulating film of a transistor included in the pixel 104 and the driving circuit 108. The insulating film 158 may be made of the same material as that of the base film 156.

A signal line 172 may be arranged on the display region 116 over the insulating film 158. The signals supplied from the driving circuit 108 to the respective pixels 104 shown in FIG. 1 are transmitted through the signal line 172. Alternatively, the signal line 172 may function as a power supply line that supplies a constant potential to the pixels 104. As the signal line 172, for example, a material containing titanium, aluminum, copper, molybdenum, or the like as a main component can be used, further, a single layer or a stacked layer thereof can be used.

Over the signal line 172 and the insulating film 158, an interlayer film 160 may be arranged over the signal line 172. The interlayer film 160 may also function as a planarization film of the signal line 172. The interlayer film 160 may be made of the same material as that of the base film 156.

Over the interlayer film 160, the terminal wiring 138 connecting to the sensor wiring 126 at the contact hole 136 may be arranged. The terminal wiring 138 may function as a wiring that conveys a signal between the external driving circuit and the touch sensor 106 shown in FIG. 1, as described above. The terminal wiring 138 may be made of a material similar to that of the signal line 172.

Over the terminal wiring 138, an insulating layer 142 may be arranged. The insulating layer 142 is located between the first step portion 112 and the second step portion 114. The insulating layer 142 covers an end portion of the terminal wiring 138. The insulating layer 142 may be formed similarly to an insulating film 154 described below. The insulating layer 142 may be made of the same material as the insulating film 154.

Over the interlayer film 160 and the signal line 172, the planarization layer 174 may be arranged at the display region 116. Further, the first step portion 112 and the second step portion 114 are arranged on the interlayer film 160 of the peripheral region 118. The first step portion 112 and the second step portion 114 are arranged between the pixel 104 located in the display region 116 and the terminal electrode 124 located in the peripheral region 118. The first step portion 112 is arranged between the pixel 104 and the second step portion 114. The second step portion 114 is arranged with an overlap with the terminal wiring 138 on the interlayer film 160. The second step portion 114 is arranged between the first step portion 112 and the terminal electrode 124.

The first step portion 112 may be formed of a stacked structure. The first step portion 112 is formed of, for example, a stacked structure of a planarization layers 111 and an insulating layer 113 as shown in FIG. 4. A thickness of the first step portion 112 or a height in a cross-sectional view is a sum of thicknesses of the planarization layers 111 and insulating layer 113. The planarization layer 111 may be formed by removing the planarization layer 174 along an outer periphery of the display region 116. The planarization layer 111 formed by removing the planarization layer 174 along the outer periphery of the display region 116 forms a step on the substrate 102. The insulating layer 113 is stacked on the planarization layer 111 having the step formed thereon, and the first step portion 112 is formed. As described above, the first step portion 112 having a sum of the stacked films as the film thickness or the height is a structure higher than that of the other structures on the substrate 102. Accordingly, the first step portion 112 may retain a first organic insulating layer 180 covering the display region 116, which will be described later, in the display region 116.

The second step portion 114 may be formed in the same manner as the first step portion 112. For example, as shown in FIG. 4, the second step portion 114 may be formed by stacking a planarization layer 117 and an insulating layer 115. The planarization layer 117 may be formed by the planarization layer 174. The planarization layer 117 formed by being removed along the outer periphery of the planarization layer 111 forms a step on the substrate 102. The insulating layer 115 is stacked on the planarization layer 117 having the step formed thereon, and the second step portion 114 is formed. By forming the second step portion 114 in this manner, the overcoat layer 168 can be retained in the second step portion 114. Accordingly, since the mounting pad 110 is not covered with the overcoat layer 168, it can be smoothly connected to the driving IC such as COF without removing the overcoat layer 168.

Further, the insulating film 154 contiguous with the second step portion 114 may be arranged on the terminal wiring 138. The insulating film 154 may be formed simultaneously with the second step portion 114. For example, the second step portion 114 can be formed by arranging the planarization layer 117 up to a top of the terminal wiring 138, arranging a full-tone mask on the planarization layer 117 corresponding to the second step portion 114, arranging a halftone mask from an end portion of the planarization layer 117 to the top of the terminal wiring 138, performing exposure, and developing and firing. The halftone mask is a photomask having a non-uniform light transmittance and a low light transmittance compared to the full-tone mask.

Here, the insulating film 154 may include the terminal wiring 138 that is exposed from the insulating film 154 in the COF installation region 128, and may be the terminal electrode 124 of the mounting pad 110.

A material similar to that of the signal line 172 or the terminal wiring 138 can be used as a material used for the terminal 124. The planarization layer 174, the planarization layer 111, the planarization layer 117, and the insulating film 154 can be made from photo-sensitive organic resin materials, including acrylic resins, polysiloxanes, polyimides, polyesters, and the like, and can function as an organic insulating layer. Further, the insulating layer 113 and the insulating layer 115 may be made of a photosensitive organic resin material including an epoxy-resin, an acrylic-resin, or the like.

Further, a spacer 176 and a partition wall layer 170 may be arranged on the planarization layer 174. The partition wall layers 170 function as partition walls that define the pixels 104. The partition wall layers 170 are arranged so as to cover electrode end portions of light emitting elements arranged in the pixels 104. The spacer 176 may be arranged on the partition wall layers 170 and may have a function of supporting a fine mask used in a manufacturing process of the light emitting element of the pixel 104, for example, a vapor deposition process.

The partition wall layers 170 and the spacers 176 can be formed from the same layers. For example, a resin film may be formed on the planarization layer 174 and a SPC mask including a full-tone mask and a halftone mask may be used to separate the thick spacers 176 and the thin partition wall layers 170 from the same layer. As the spacer 176 and the partition wall layers 170, an organic resin material such as an epoxy resin or an acrylic resin used for the insulating layer 113 or the insulating layer 115 can be used.

A sealing layer 166 is arranged on the spacer 176 and the partition wall layers 170 and is arranged on a region surrounded by the first step portion 112 and the second step portion 114 in a planar view. The sealing layer 166 includes a plurality of insulating layers, and the plurality of insulating layers may be arranged with different functions. For example, as shown in FIG. 4, the sealing layer 166 includes a first inorganic insulating layer 178, a first organic insulating layer 180, and a second inorganic insulating layer 182.

The region surrounded by the first step portion 112 and the second step portion 114 includes the display region 116, and in the case where an organic EL element is used for the pixel 104, the first inorganic insulating layer 178 covers the organic EL element, thereby the entry of impurities into the display region may be suppressed. As the first inorganic insulating layer 178, for example, an inorganic compound such as silicon oxide or silicon nitride can be used.

The first organic insulating layer 180 is arranged in a region above the first inorganic insulating layer 178 and surrounded by the first step portion 112 in a planar view. The first organic insulating layer 180 is arranged along the first step portion 112 so as not to exceed the planarization layers 111 or the first step portion 112. Further, the first organic insulating layer 180 may be planarized over the pixel 104 and may protect a light emitting element from contaminants if the pixel 104 is arranged with the light emitting element. The first organic insulating layer 180 may be made of the same material as that of the insulating film 154.

The second inorganic insulating layer 182 may be arranged on the first organic insulating layer 180 and in the region surrounded by the first step portion 112 and the second step portion 114 in a planar view. The second inorganic insulating layer 182 contacts the first inorganic insulating layer 178 at a region outside of the first organic insulating layer. Accordingly, the first inorganic insulating layer 178 and the second inorganic insulating layer 182 cover the first step portion 112 and extend outward of the first step portion 112. With such a configuration, the first inorganic insulating layer 178 and the second inorganic insulating layer 182 can seal the first organic insulating layer 180. As the second inorganic insulating layer 182, for example, an inorganic compound such as silicon nitride can be used.

A plurality of different types of films, such as the first organic insulating layer 180 and the second inorganic insulating layer 182 described above, can be planarized on the pixel 104 and protected from contaminants of the light emitting element arranged on the pixel 104, so that in the display region 116, a structure, such as the touch sensor 106, can be arranged on the pixel 104.

Above the second inorganic insulating layer 182, the sensor electrode 122 may be arranged at the display region 116. Since the sensor electrode 122 is arranged in the display region 116, a transparent conductive film which can ensure visibility of a displayed image can be used. The transparent conductive film uses light transmittance oxide having conductivity, such as indium-tin oxide (ITO), indium-zinc oxide (IZO), zinc oxide (ZnO), or indium-tin-zinc oxide (ITZO), for example.

Over the sealing layer 166, the sensor wiring 126 is arranged which connects to the sensor electrode 122. Specifically, the sensor wiring 126 is arranged on the second inorganic insulating layer 182 of the sealing layer 166. The sensor wiring 126 extends over the first step portion 112 to the contact hole 136 for connecting to the terminal wiring 138 via the contact hole 136 located between the first step portion 112 and the second step portion 114. Here, the sensor wiring 126 is positioned over the second inorganic insulating layer 182, so that portions of the first inorganic insulating layer 178, the second inorganic insulating layer 182, and the insulating layer 142 are removed to form the contact hole 136 for connection with the terminal wiring 138. The sensor wiring 126 may be made of a material similar to that of the signal line 172 and the terminal wiring 138.

In addition, the overcoat layer 168 is arranged over the sensor electrode 122 and the sensor wiring 126 to cover them. The overcoat layer 168 is arranged so as to extend over the contact hole 136. The overcoat layers 168 are arranged in a region surrounded by the second step portion 114 in a planar view. The overcoat layer 168 may be formed of the same material as that of the first organic insulating layer 180.

The counter substrate 120 may be arranged over the overcoat layers 168. In FIG. 4, although the counter substrate 120 is arranged so as to overlap the overcoat layer 168, it may be arranged on a structure arranged on the substrate 102. A film, a glass, or the like having a function of a polarization plate can be used for the counter substrate 120. The counter substrate 120 has a function of protecting a structure arranged on the substrate 102, for example, the pixel 104, the touch sensor 106, and the like. Further, when the counter substrate 120 and the substrate 102 are bonded together, they can be bonded together between the counter substrate 120 and the substrate 102 using an adhesive layer 169. An adhesive may be used for the adhesive layer 169. The adhesive may be an adhesive having a refractive index close to materials of the counter substrate 120 such as OCA (Optical Clear Adhesive). By applying such an adhesive to a surface facing a structure of the substrate 102, the adhesive layer 169 can be used between the counter substrate 120 and the substrate 102 to bond them together.

### 2-2. Partial Structure-1

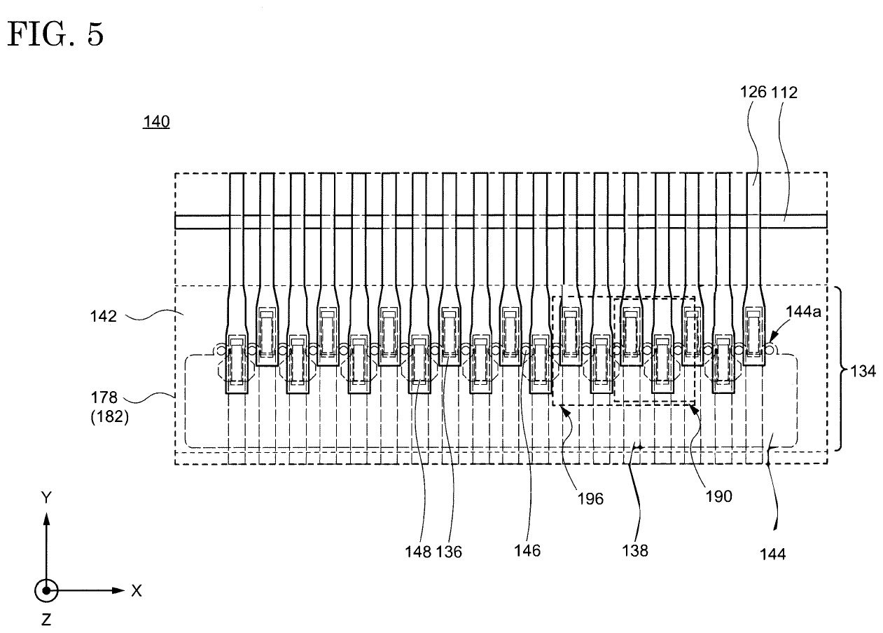

FIG. 5 shows an enlarged schematic top view of a partial structure 140 enclosed by a dashed line shown in FIG. 1. Hereinafter, the same configurations as those in FIG. 1 to FIG. 4 will be omitted in some cases. In FIG. 5, a configuration located above the overcoat layer 168, for example, the counter substrate 120, is omitted.

FIG. 5 shows a periphery of the contact portion 134. In order to connect the sensor wiring 126 and the terminal wiring 138, the contact hole 136 is arranged in a portion where the sensor wiring 126 and the terminal wiring 138 overlap. As described above, the contact hole 136 is formed by removing each portion of the insulating layer 142, the first inorganic insulating layer 178, and the second inorganic insulating layer 182. A contact hole 148 having an outer shape smaller than an outer shape of the contact hole 136 is formed inside the contact hole 136. The insulating layer 142 is made of a material differing in properties from the first inorganic insulating layer 178 and the second inorganic insulating layer 182. The contact hole 136 is formed by removing the portion of the insulating layer 142, and the contact hole 148 is formed by removing the portion of the first inorganic insulating layer 178 and the portion of the second inorganic insulating layer 182. Therefore, the outer shape of the contact hole 136 and an outer shape of the contact hole 148 are different from each other. In the following description, the contact hole 148 is located inside the contact hole 136, and thus can be replaced with the contact hole 136.

A plurality of contact holes 136 is arranged. The plurality of contact holes 136 is arranged along the first step portion 112 and are alternately arranged on the display region 116 side and an end portion side of the substrate 102. In the case where the display region 116 has a circular shape or the like and is not a polygonal shape such as a quadrangle, the contact holes 136 are arranged along a direction in which the sensor electrode 122 is arranged, for example, the row direction (direction X) as shown in FIG. 1.

The contact holes 136 are arranged between the display region 116 and the substrate 102 end portion so that the neighboring contact holes 136 are arranged at different positions. Here, the different positions are different positions along the sensor wiring 126 between the contact hole 136 and the first step portion 112. By arranging the contact holes 136 at the different positions as described above, a distance between adjacent contact holes 136 can be increased. By increasing the distance between the adjacent contact holes 136, the margin is increased in the arrangement of the contact holes 136. Therefore, an inclination angle θ of the contact hole 136 to be described later can be reduced.

An insulating layer 144 is arranged in the contact portion 134. The insulating layer 144 is arranged at the end portion side of the substrate 102 than the contact hole 136. The insulating layer 144 is arranged across the plurality of contact holes 136. The insulating layer 144 is arranged so as to surround an outer periphery of the contact hole 136. The insulating layer 144 surrounding the outer periphery of the contact hole 136 of the present embodiment has a substantially rectangular shape. Further, the insulating layer 144 surrounding the outer periphery of the contact hole 136 has a shape recessed toward the end portion side of the substrate 102 with respect to a round rectangular shape and a shape protruding toward the display region 116 side.

The insulating layer 144 is arranged so as to cover at least a portion of the contact hole 136. For example, as shown in FIG. 5, the insulating layer 144 is arranged so as to cover an end portion of the contact hole 136 facing away from the display region 116. A protrusion part 144a protruding toward the display region 116 of the insulating layer 144 is located between the plurality of contact holes 136.

Although the protrusion part 144a between the contact holes 136 is a rounded shape in FIG. 5, the protrusion part 144a may be any shape that matches a shape of an insulating layer 146. For example, if the insulating layer 144 is rectangular, the protruding shape of the insulating layer 146 may be any shape having a rectangular shape.

The insulating layer 146 is arranged on the insulating layer 144. The insulating layer 146 is arranged on a part of insulating layer 144 protruding from the display region 116. The insulating layer 146 is positioned to fit within an outer shape of a protruding geometry of the insulating layer 144. An outer shape of the insulating layer 146 in a planar view may be an octagon or a shape that complements the octagon, for example, a shape having a circular shape, as long as the protrusion part 144a is a polygon such as an octagon. The insulating layer 146 is arranged between the plurality of contact holes 136. A plurality of insulating layers 146 is respectively arranged between the plurality of contact holes 136. The insulating layer 146 is arranged on the outer periphery of the contact hole 136. At least one insulating layer 146 may be arranged on the outer periphery of each contact hole 136. The insulating layer 146 has a circular shape, and as shown in FIG. 5, the insulating layer 146 can have a polygonal shape, as described above.

The sensor wiring 126 is arranged so as to cross the first step portion 112 and cover the contact hole 136. The sensor wiring 126 differs in a position of an end portion in the contact portion 134. An end portion of the sensor wiring 126 is alternately arranged in accordance with the positions of the plurality of contact holes 136 in the case where the plurality of contact holes 136 is alternately arranged on the end portion side and the display region 116 side of the substrate 102, as shown in FIG. 5. Specifically, in the case where the sensor wiring 126 is made to overlap the contact hole 136 closer to the end portion of the substrate 102 than the adjacent contact hole 136, the substrate 102 on an end portion side of the sensor wiring 126 has an end portion closer to the substrate 102 than the end portion of the sensor wiring 126 overlapping the adjacent contact hole 136.

The sensor wiring 126 is positioned to overlap a depression of the insulating layer 144. The sensor wiring 126 overlaps at least a portion of an outer periphery of a recess of the insulating layer 144. The sensor wiring 126 overlaps at least a portion of a protrusion part of the insulating layer 144. The sensor wiring 126 may be arranged between the plurality of insulating layers 146. An end portion indicating an outer shape of the sensor wiring 126 is located on the outer periphery of the contact hole 136. The end portion indicating the outer shape of the sensor wiring 126 is located at the insulating layer 142, the insulating layer 144, and the insulating layer 146 at the outer periphery of the contact hole 136.

The sensor wiring 126 may be wider in a region covering the contact hole 136. The sensor wiring may be narrower than the first step portion 112. As described above, by appropriately changing the width of the sensor wiring 126, the sensor wiring 126 and the terminal wiring 138 can be sufficiently connected, and a resistance of the longer sensor wiring 126 can be lowered.

The terminal wiring 138 is arranged to be larger than the outer shape of the contact hole 136 in a planar view. As shown in FIG. 5, the terminal wiring 138 has a width larger than the width of the contact hole 136 in the direction X and the direction Y. The terminal wiring 138 overlaps the sensor wiring 126 in the contact hole 136. The terminal wiring 138 differs in the position of the end portion in the contact portion 134. An end portion of the terminal wiring 138 is alternately arranged in accordance with the positions of the plurality of contact holes 136 in the case where the plurality of contact holes 136 is alternately arranged on the end portion side and the display region 116 side of the substrate 102, as shown in FIG. 5. Specifically, an end portion of the terminal wiring 138 on the display region 116 side is closer to the display region 116 than an end portion of the terminal wiring 138 overlapping the adjacent contact hole 136, in the case where the terminal wiring 138 overlaps the plurality of contact holes 136 closer to the display region 116 than the adjacent contact holes 136.

### 2-3. Partial Structure-2

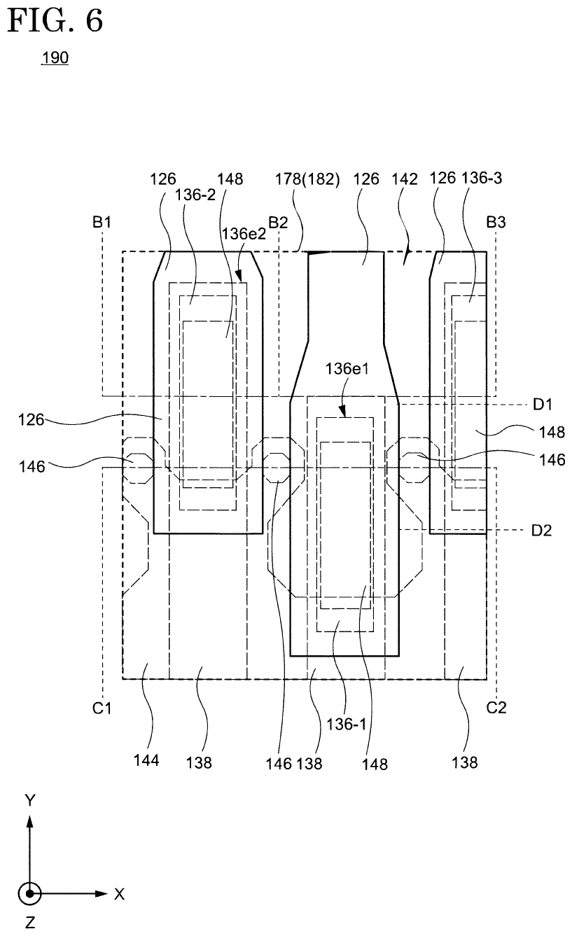

FIG. 6 shows an enlarged schematic top view of a partial structure 190 enclosed by a dashed line shown in FIG. 5. Hereinafter, the same configurations as those in FIG. 1 to FIG. 5 will be omitted in some cases.

Adjacent contact holes 136 are arranged at different positions as described above. In the case where the adjacent contact holes 136 are arranged at different positions, an end portion 136e1 on the display region 116 side of the contact hole 136 located on the end portion side of the substrate 102 is arranged between the adjacent contact holes 136. In the case where the adjacent contact holes 136 are arranged at different positions from each other, the end portion 136e1 on the display region 116 side of the contact hole 136-1 located on the end portion side of the substrate 102 is closer to the end portion of the substrate 102 than an end portion 136e2 on the display region 116 side of an adjacent contact hole 136-2. In the case where the adjacent contact holes 136 are arranged at different positions, the end portion 136e2 of the display region 116 side of the contact hole 136-2 located on the display region 116 side is closer to the display region 116 than the end portion 136e1 of the display region 116 side of the adjacent contact hole 136-1.

The contact hole 136 is arranged so as to sandwich the contact hole 136 and the insulating layer 146 adjacent to each other. The sensor wiring 126 covers an entirety of the contact hole 136 and the insulating layer 142 of the outer periphery of the contact hole 136 as described above. The sensor wiring 126 covers a portion of the insulating layer 146. The sensor wiring 126 covers a portion of the protrusion part and a recessed portion of the insulating layer 144.

### 2-4. Cross-Sectional Structure-1

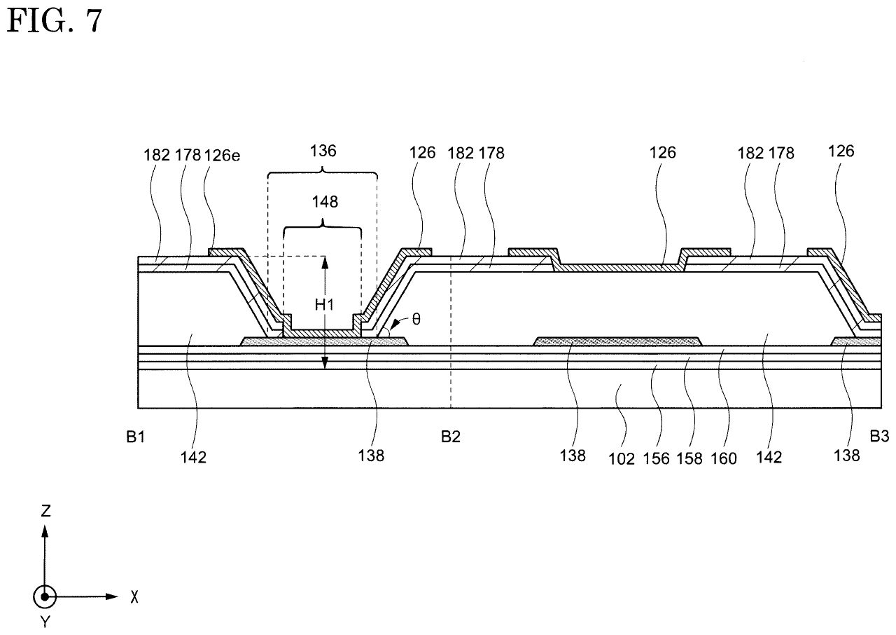

FIG. 7 shows a schematic end view along a dashed line B1-B3 shown in FIG. 6. Hereinafter, the same configurations as those in FIG. 1 to FIG. 6 will be omitted in some cases.

As described above, the contact hole 136 is formed by removing a part of the insulating layer 142. The contact hole 148 is formed by removing a portion of the first inorganic insulating layer 178 and the second inorganic insulating layer 182 arranged on the insulating layer 142.

The sensor wiring 126 covers the contact hole 136 and the contact hole 148. The sensor wiring 126 is located on the insulating layer 142, the first inorganic insulating layer 178, and the second inorganic insulating layer 182. The sensor wiring 126 covers the terminal wiring 138 exposed from the insulating layer 142, the first inorganic insulating layer 178, and the second inorganic insulating layer 182. The sensor wiring 126 is arranged on the terminal wiring 138. The sensor wiring 126 connects to the terminal wiring 138 by covering the terminal wiring 138.

The sensor wiring 126 covers an inclined surface of the insulating layer 142 formed by removing a portion of the insulating layer 142. The sensor wiring 126 covers inclined surfaces of the first inorganic insulating layer 178 and the second inorganic insulating layer 182 formed by removing portions of the first inorganic insulating layer 178 and the second inorganic insulating layer 182.

The sensor wiring 126 is arranged on the second inorganic insulating layer 182. As shown in FIG. 7, although the first inorganic insulating layer 178 and the second inorganic insulating layer 182 are arranged in a stacked manner between the sensor wiring 126 and the insulating layer 142, in the case where a plurality of inorganic insulating layers is arranged in this manner, they may be treated as a single inorganic insulating layer.

An end portion 126e of the sensor wiring 126 is located on the insulating layer 142, the first inorganic insulating layer 178 and the second inorganic insulating layer 182. The end portion 126e of the sensor wiring 126 corresponds to an end portion indicating an outer shape of the sensor wiring 126 in a planar view. For example, the end portion 126e of the sensor wiring 126 is included in an end portion indicating the outer shape of the sensor wiring 126 located at the outer periphery of the contact hole 136 shown in FIG. 6 or a borderline between the sensor wiring 126 and the second inorganic insulating layer 182.

The end portion 126e of the sensor wiring 126 sandwiches the first inorganic insulating layer 178 and the second inorganic insulating layer 182 with the insulating layer 142. In other words, the first inorganic insulating layer 178 and the second inorganic insulating layer 182 are located between the end portion 126e of the sensor wiring 126 and the insulating layer 142.

The end portion 126e of the sensor wiring 126 is located on a part of the first inorganic insulating layer 178 that is in contact with the insulating layer 142. In the case where the first inorganic insulating layer 178 is not arranged on the insulating layer 142, the end portion 126e of the sensor wiring 126 is located on a part of the second inorganic insulating layer 182 that is in contact with the insulating layer 142.

As shown in FIG. 7, a height of the sensor wiring 126 is a height H1 from a surface of the substrate 102 to the end portion 126e of the sensor wiring 126. In this case, the surface of the substrate 102 may be a borderline between the under film 156 and the substrate 102 in a cross-sectional view. A borderline between the sensor wiring 126 and the second inorganic insulating layer 182 in the end portion 126e in a cross-sectional view may comprise the area up to the end portion 126e of the sensor wiring 126 described above

### 2-5. Cross-Sectional Structure-2

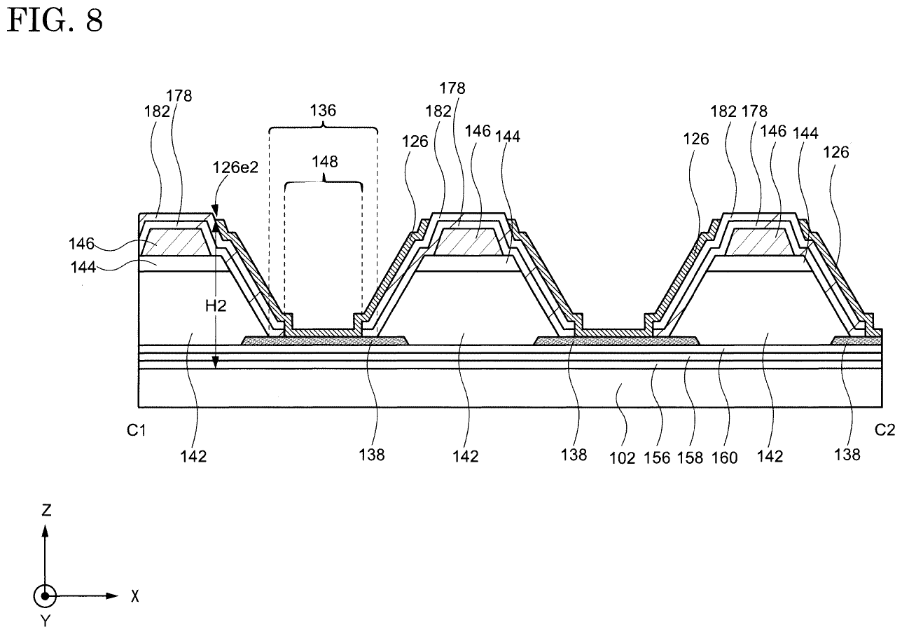

FIG. 8 shows a schematic end view along a dashed line C1-C2 shown in FIG. 6. Hereinafter, the same configurations as those in FIG. 1 to FIG. 7 will be omitted in some cases.

The insulating layer 146 is arranged on the insulating layer 142. Further, the insulating layer 146 can be made higher in the cross-sectional view (in a direction Z) than an upper surface of the insulating layer 142 by being laminated with the insulating layer 144. A stacked structure of the insulating layer 144 and the insulating layer 146 can be formed in a manner similar to the partition wall layer 170 and the spacer 176. For example, a resin film can be formed on the insulating layer 142 and the narrow insulating layer 146 and the wide insulating layer 144 can be created from the same layers using the SPC mask including the full-tone mask and the halftone mask. In this case, the insulating layer 146 and the insulating layer 144 may be made of the same materials as the partition wall layer 170 and the spacer 176.

A height from an upper surface of the substrate 102 to the upper surface of the insulating layer 146 is increased by a sum of the film thicknesses of the insulating layer 144 and the insulating layer 146 as compared to where there is no structure such as the insulating layer 146 on the insulating layer 142 by laminating the insulating layer 146 and the insulating layer 144. By arranging the insulating layer 146 on an outer peripheral portion of the contact hole 136, a height of the outer peripheral portion of the contact hole 136 from the surface of the substrate 102 to a surface of the second inorganic insulating layer 182 or the first inorganic insulating layer 178 on the insulating layer 142 is not the same. In other words, the outer peripheral portion of the contact hole 136 differs from the surface of the substrate 102 to the surface of the second inorganic insulating layer 182 and the first inorganic insulating layer 178 on the insulating layer 142 in a cross-sectional view.

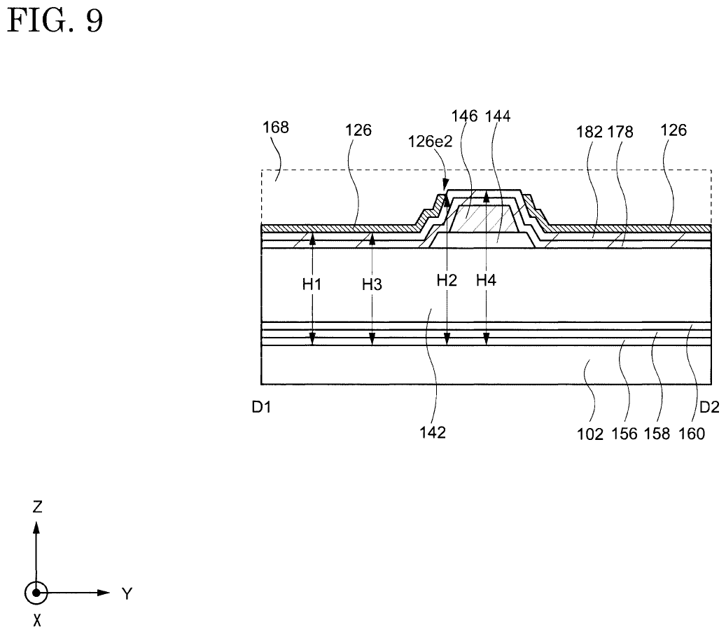

Referring now to FIG. 9, heights of the first inorganic insulating layer 178 and the second inorganic insulating layer 182 at the outer peripheral portion of the contact hole 136 will be described. FIG. 9 shows a schematic end view along a dashed line D1-D2 shown in FIG. 6.

As shown in FIG. 9, a height H3 and a height H4 of the surface of the second inorganic insulating layer 182 from the surface of the substrate 102 differ at the outer periphery of the contact hole 136.

The height H3 indicates a distance between the surface of the sensor wiring 126 in contact with the second inorganic insulating layer 182 and a surface of a region that does not overlap a stacked structure of the insulating layer 146 and the insulating layer 144 and that faces the second inorganic insulating layer 182 of the substrate 102. In other words, the height H3 indicates a distance between a surface of the sensor wiring 126 that is in contact with the second inorganic insulating layer 182 that is located above a portion where the first inorganic insulating layer 178 is in contact with the insulating layer 142 and a surface of the substrate 102 that is in contact with the second inorganic insulating layer 182 in a region overlapping a portion where the first inorganic insulating layer 178 is in contact with the insulating layer 142. The height H3 corresponds to the height H1 shown in FIG. 7.

The height H4 indicates a distance between a surface of the overcoat layer 168 in contact with the second inorganic insulating layer 182 and a surface of the substrate 102 facing the second inorganic insulating layer 182 in a region where the substrate 102 overlaps the stacked structure of the insulating layer 146 and the insulating layer 144. In other words, the height H4 indicates a distance between a surface where the overcoat layer 168 contacts the second inorganic insulating layer 182 located above a portion of the first inorganic insulating layer 178 that contacts the insulating layer 146 and a surface of the substrate 102 that faces the second inorganic insulating layer 182. The height H4 described above may be shown by replacing the overcoat layer 168 with the sensor wiring 126 in the case where the sensor wiring 126 is arranged between the overcoat layer 168 and the second inorganic insulating layer 182.

As described above, in the outer peripheral portion of the contact hole 136, the height of the first inorganic insulating layer 178 or the second inorganic insulating layer 182 differs due to the difference in the distance from the surface of the substrate 102 to the surface of the second inorganic insulating layer 182 or the surface of the first inorganic insulating layer 178 on insulating layer 142 in the cross-sectional view.

Accordingly, the sensor wiring 126 located on the second inorganic insulating layer 182 and the first inorganic insulating layer 178 have parts having different heights at the outer peripheral portion of the contact hole 136. In addition, in the case where a layer between the sensor wiring 126 and insulating layer 142 at the outer peripheral portion of the contact hole 136 is constructed of either the second inorganic insulating layer 182 or the first inorganic insulating layer 178, the layer may be located on the sensor wiring 126 and/or on any of the second inorganic insulating layer 182 or the first inorganic insulating layer 178.

The sensor wiring 126 is also positioned at a different height from the surface of the substrate 102 because the sensor wiring 126 located on the outer periphery of the contact hole 136 is located on the first inorganic insulating layer 178 and the second inorganic insulating layer 182 at different heights from the surface of the substrate 102. Specifically, as shown in FIG. 7 and FIG. 8, the height H1 of the end position 126e of the sensor wiring 126 and the height H2 of the end portion 126e2 of the sensor wiring 126 are different heights.

The end portion 126e of the sensor wiring 126 is located on a portion of at least either the first inorganic insulating layer 178 or the second inorganic insulating layer 182 that is in contact with the insulating layer 142, as described above.

The end portion 126e2 of the sensor wiring 126 is located on a portion of at least either the first inorganic insulating layer 178 or the second inorganic insulating layer 182 that is in contact with the insulating layer 146. Therefore, the height H1 of the end portion 126e of the sensor wiring 126 and the height H2 of the end portion 126e2 of the sensor 126 are different heights. Although the end portion of the sensor wiring 126 located above the contact hole 136 shown in FIG. 6 is located above the same first inorganic insulating layer 178 and the second inorganic insulating layer 182, the distance differs in height H1 and height H2 depending on whether the insulating layer 146 is located between the first inorganic insulating layer 178 and the second inorganic insulating layer 182, and the substrate 102.

The end portion 126e of the sensor wiring 126 is not located above the insulating layer 146 and is shown in FIG. 8. However, if the adjacent sensor wiring 126 is spaced apart, the end portion 126e of the sensor wiring 126 may be located above the insulating layer 146.

Hereinafter, the insulating layer 146 will be described in detail. The insulating layer 146 is located between the substrate 102 and the first inorganic insulating layer 178. The insulating layer 146 is located between the substrate 102 and the second inorganic insulating layer 182. The insulating layer 146 is located between the insulating layer 142 and the sensor wiring 126. The insulating layer 146 is located between the first inorganic insulating layer 178 and the insulating layer 142. The insulating layer 146 is located between the insulating layer 142 and the second inorganic insulating layer 182.

The insulating layer 146 is covered with the first inorganic insulating layer 178. The sides of the insulating layer 146 are also covered with the first inorganic insulating layer 178. The insulating layer 146 is covered by the second inorganic insulating layer 182. The sides of the insulating layer 146 are also covered with the second inorganic insulating layer 182. The insulating layer 146 is covered by the sensor wiring 126. The side of the insulating layer 146 are also covered with the sensor wiring 126.

### 3. Comparative Example

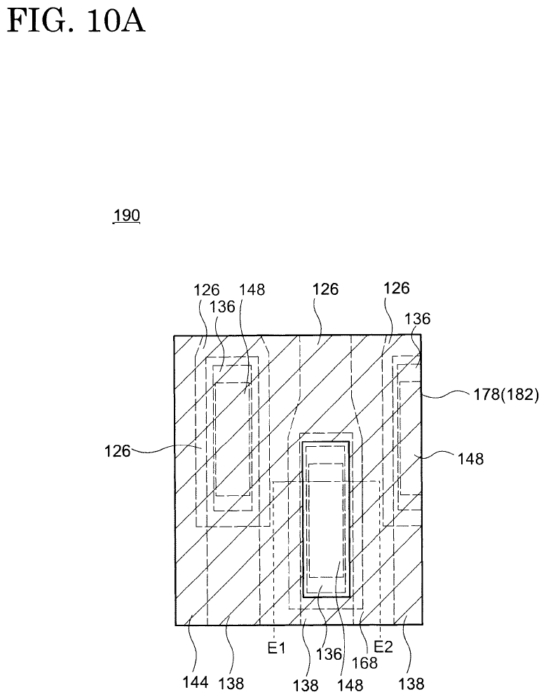

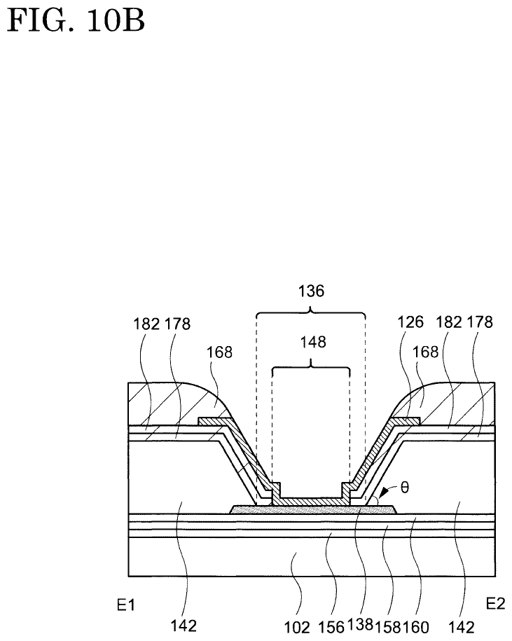

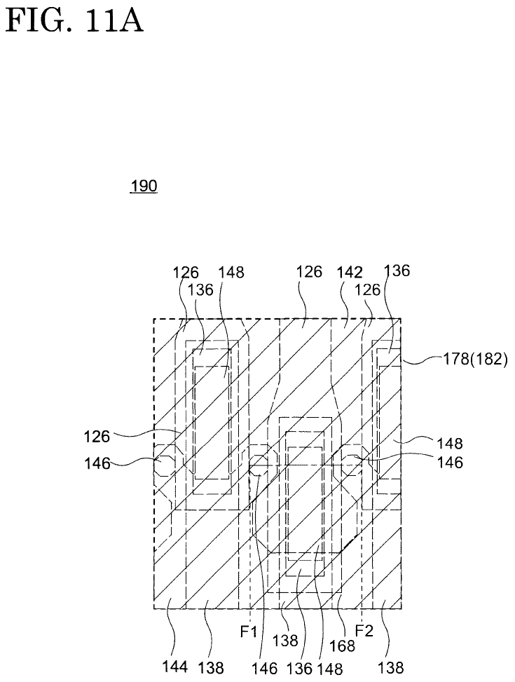

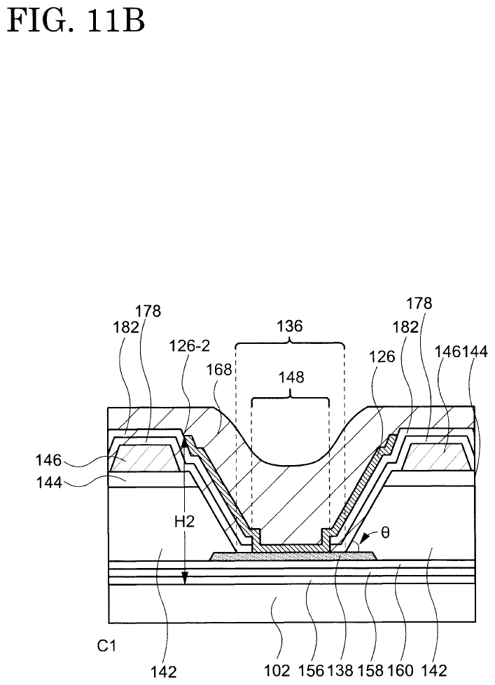

Next, the overcoat layer 168 will be described referring to FIG. 10A, FIG. 10B, FIG. 11A, and FIG. 11B. FIG. 10A and FIG. 10B are schematic top view and end views of a display device according to a comparative example. FIG. 11A and FIG. 11B are schematic top view and end views of the display device 100.

FIG. 10A shows a comparative example in which the insulating layer 146 is not arranged at the outer peripheral portion of the contact hole 136. If the overcoat layer 168 is formed after the sensor wiring 126 is formed, the sensor wiring 126 may be exposed because the overcoat layer 168 is not formed in the contact hole 136 as shown in FIG. 10A. In FIG. 10A, the overcoat layers 168 are shown hatched.

FIG. 10B shows a schematic end view along a dashed line E1-E2 shown in FIG. 10A. As shown in FIG. 10A, the overcoat layer 168 may not be formed in the contact hole 136, the overcoat layer 168 may remain on the outer periphery of the contact hole 136, and the sensor wiring 126 may be exposed from the overcoat layer 168. In FIG. 10A and FIG. 10B of the drawings, although the sensor wiring 126 is entirely exposed from the overcoat layer 168 in the contact hole 136, the sensor wiring 126 may be partially exposed from the overcoat layer 168.

FIG. 11A shows the present embodiment in which the insulating layer 146 is arranged at the outer periphery of the contact hole 136. In the case where the overcoat layer 168 is formed after the sensor wiring 126 is formed, the overcoat layer 168 is formed in the contact hole 136 and the sensor wiring 126 is not exposed from and covered by the overcoat layer 168, as shown in FIG. 11A. In FIG. 11A, the overcoat layers 168 are shown hatched.

FIG. 11B shows a schematic end view along a dashed line F1-F2 shown in FIG. 11A. As shown in FIG. 11A, the overcoat layers 168 are formed in the contact holes 136. The overcoat layer 168 enters the contact hole 136 and the sensor wiring 126 is covered without being exposed from the overcoat layer 168.

In the display device 100, by arranging the insulating layer 146 in the outer peripheral portion of the contact hole 136, unevenness is arranged in the insulating layer of the outer peripheral portion of the contact hole 136, for example, the first inorganic insulating layer 178 and the second inorganic insulating layer 182. As described above, since the unevenness is arranged on the outer periphery of the contact hole 136, the insulating layer of the outer peripheral portion of the contact hole 136 does not have the same height from the substrate 102. By this dissimilarity, the overcoat layer 168 is unbalanced at the outer peripheral portion of the contact hole 136 and flows into the contact hole 136. Therefore, by applying the present embodiment, exposure of the sensor wiring 126 from the overcoat layer 168 is suppressed, the sensor wiring 126 can be protected, and a highly reliable display device with high yield is provided.

Further, since the plurality of contact holes 136 is arranged alternately, the distance between the adjacent contact holes 136 can be increased, so that the inclination angle θ of the contact hole 136 can be reduced. By reducing the inclination angle θ, the overcoat layer 168 easily flows into the contact hole 136. It is possible to prevent air from entering between the sensor wiring 126 and the overcoat layers 168, which is likely to occur in the case where an inclination angle of the contact hole 136 is steep. Therefore, by applying the present embodiment, coverage of the overcoat layer 168 with respect to the sensor wiring 126 is increased, the sensor wiring 126 can be protected, and a display device with high yield and high reliability can be provided.

### 4. Modifications

### 4-1. Modification 1

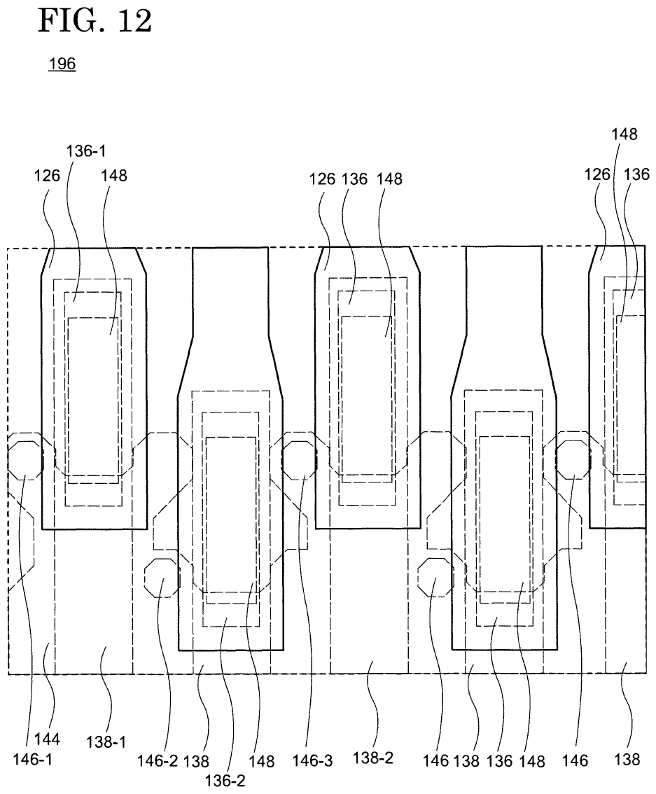

Referring to FIG. 12, a modification of the display device 100 will be described. A difference from the display device 100 shown in FIG. 1 to FIG. 11A and FIG. 11B is that the insulating layers 146 are alternately arranged to sandwich the contact hole 136. Hereinafter, the same configurations as those in FIG. 1 to FIG. 11A and FIG. 11B will be omitted in some cases.

FIG. 12 shows a modification of the partial structure 196 including the partial structure 190 shown in FIG. 5. An insulating layer 146-1 is arranged on a protrusion portion of the insulating layer 144 at the outer peripheral portion of the contact hole 136. Further, an insulating layer 146-2 is arranged obliquely from the insulating layer 146-1 arranged on the protrusion part of the insulating layer 144 with a terminal wiring 138-1 interposed therebetween. Further, an insulating layer 146-3 is arranged obliquely from the insulating layer 146-2 with the sensor wiring 126 and a terminal wiring 138-2 interposed therebetween. In this way, the plurality of insulating layers 146 is arranged alternately behind the first step portion 112 side and the substrate 102 end portion side. By arranging the insulating layers 146 alternately in this manner, the overcoat layer 168 is polygonally unbalanced at the outer peripheral portion of the contact hole 136, and the overcoat layer 168 is promoted to flow into the contact hole 136.

### 4-2. Modification 2

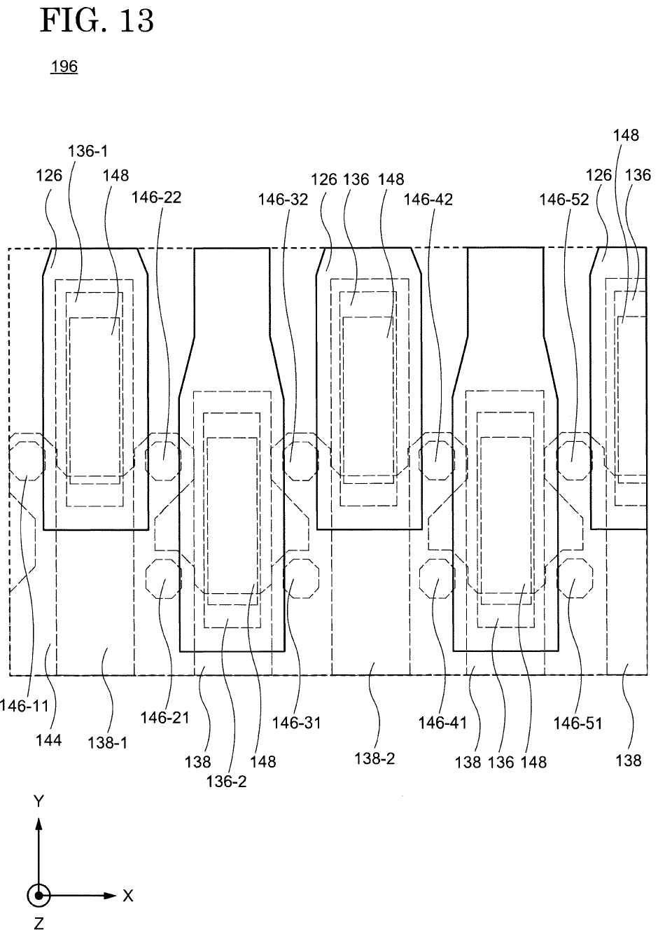

Referring to FIG. 13, a modification of the display device 100 will be described. A difference from the display device 100 shown in FIG. 1 to FIG. 12 is that the insulating layer 146 is arranged near a tip of the sensor wiring 126. Hereinafter, the same configurations as those in FIG. 1 to FIG. 12 will be omitted in some cases.

As shown in FIG. 13, the plurality of insulating layers 146 is arranged adjacently to the outer peripheral portion of the contact hole 136 on the substrate 102 end portion side, among the contact holes 136 alternately arranged on the first step portion 112 side and the substrate 102 end portion side, in a direction where the sensor wiring 126 extends from the first step portion 112. Specifically, in an outer peripheral portion of the contact hole 136-2, an insulating layer 146-21 and an insulating layer 146-22 are arranged adjacently in the direction where the sensor wiring 126 extends from the first step portion 112. At the outer periphery of the contact hole 136-2, an insulating layer 146-31 and an insulating layer 146-32 are arranged adjacently in the direction where the sensor wiring 126 extends from the first step portion 112. At this time, the insulating layer 146-21, the insulating layer 146-31, the insulating layer 146-22, and the insulating layer 146-32 are positioned to sandwich the sensor wiring 126 and terminal wiring 138, respectively.

### 4-3. Modification 3

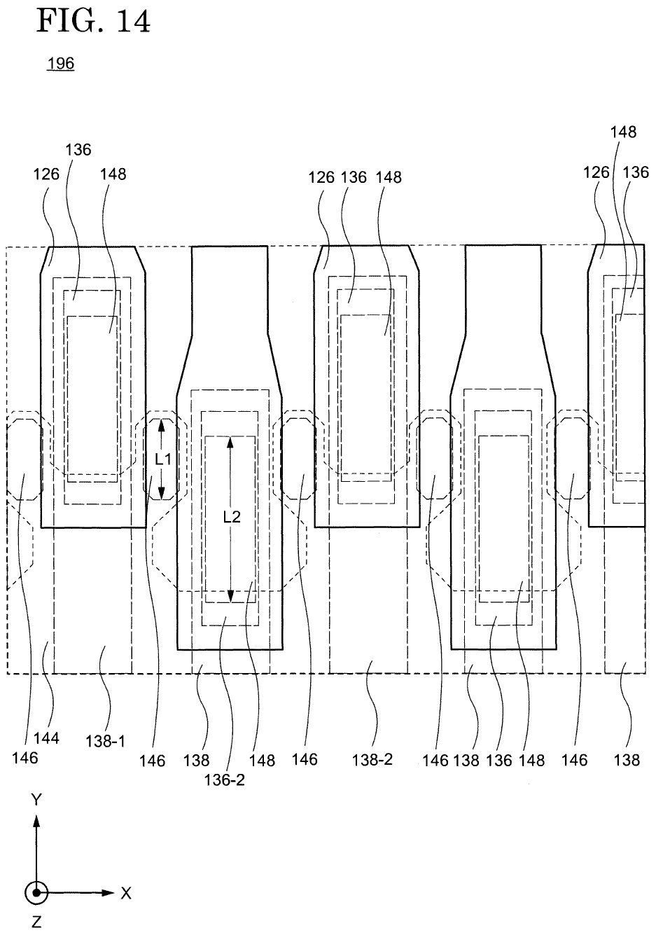

Referring to FIG. 14, a modification of the display device 100 will be described. A difference from the display device 100 shown in FIG. 1 to FIG. 13 is that shapes and sizes of the insulating layer 146 are different. Hereinafter, the same configurations as those in FIG. 1 to FIG. 13 will be omitted in some cases.

As shown in FIG. 14, the insulating layer 146 has a longitudinal direction in which the sensor wiring 126 extends from the first step portion 112. A longitudinal length L1 of the insulating layer 146 is shorter than a longitudinal L2 of the contact hole 148. In FIG. 1 to FIG. 13, the shape of the insulating layer 146 is a regular circle or a near regular octagon, but it can also be an oval, polygon, or other shape with a longitudinal direction, as shown in FIG. 14.

### 4-4. Modification 4

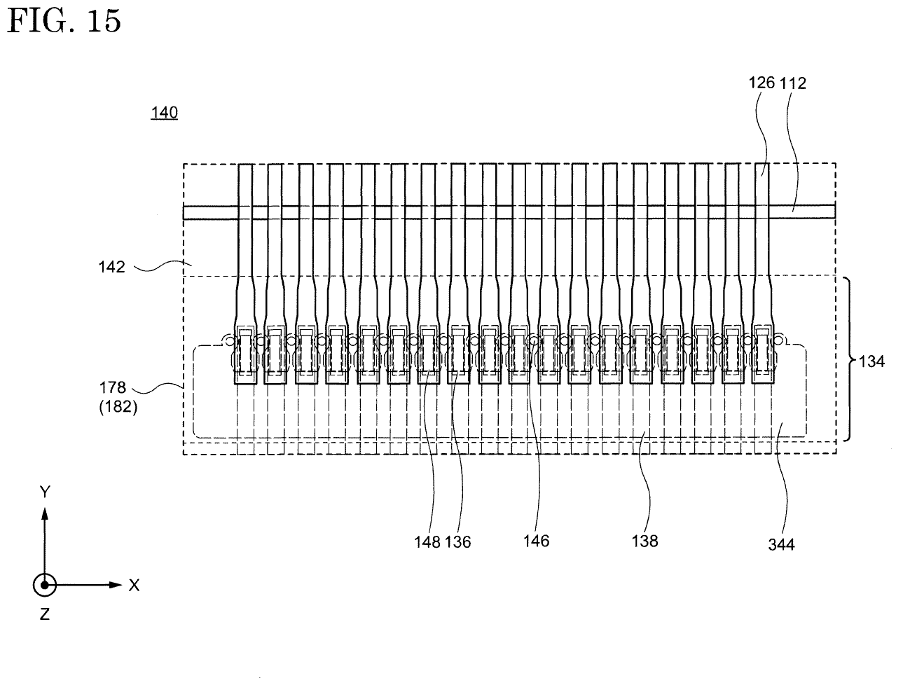

Referring to FIG. 15 to FIG. 18, a modification of the display device 100 will be described. A difference from the display device 100 shown in FIG. 1 to FIG. 14 is that the contact holes 136 are not alternately arranged. Hereinafter, the same configurations as those in FIG. 1 to FIG. 14 will be omitted in some cases.

The plurality of contact holes 136 is arranged side by side along the first step portion 112. As shown in FIG. 15, an end portion of the contact hole 136 on the first step portion 112 side and the end portion on the end portion side of the substrate 102 are arranged along the first step portion 112, respectively. The end portion of the sensor wiring 126 on the end portion side of the substrate 102 is aligned along the first step portion 112 in the same manner as the arrangement of the contact holes 136.

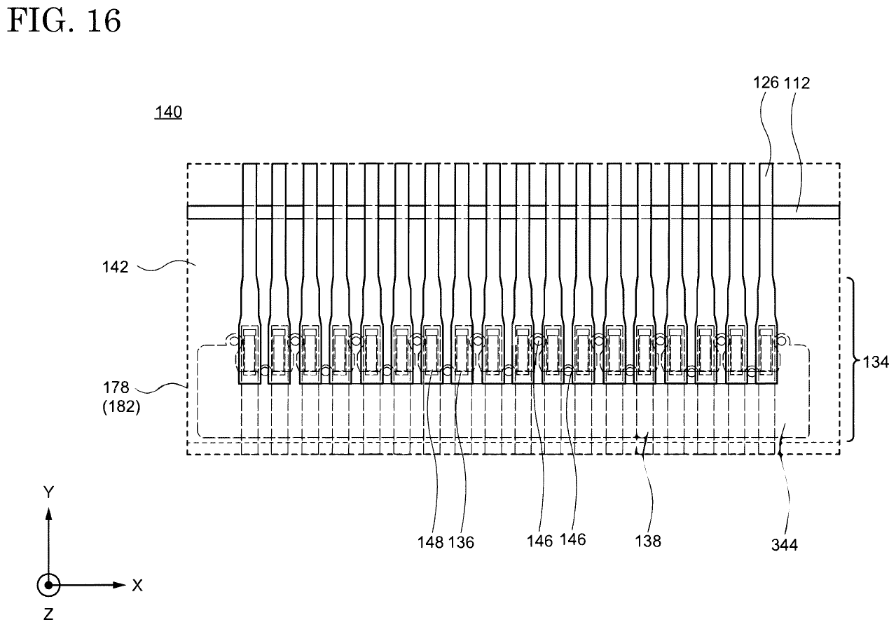

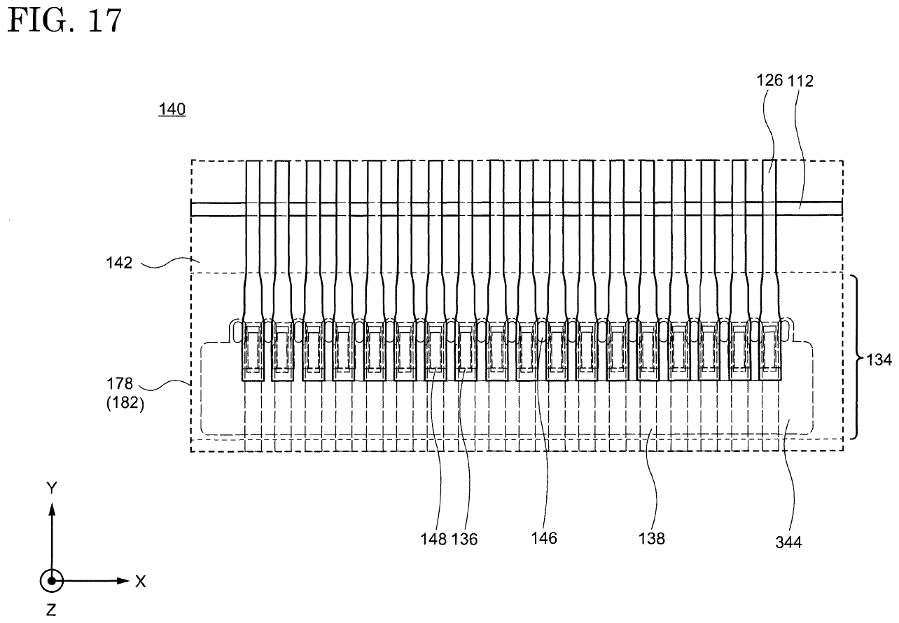

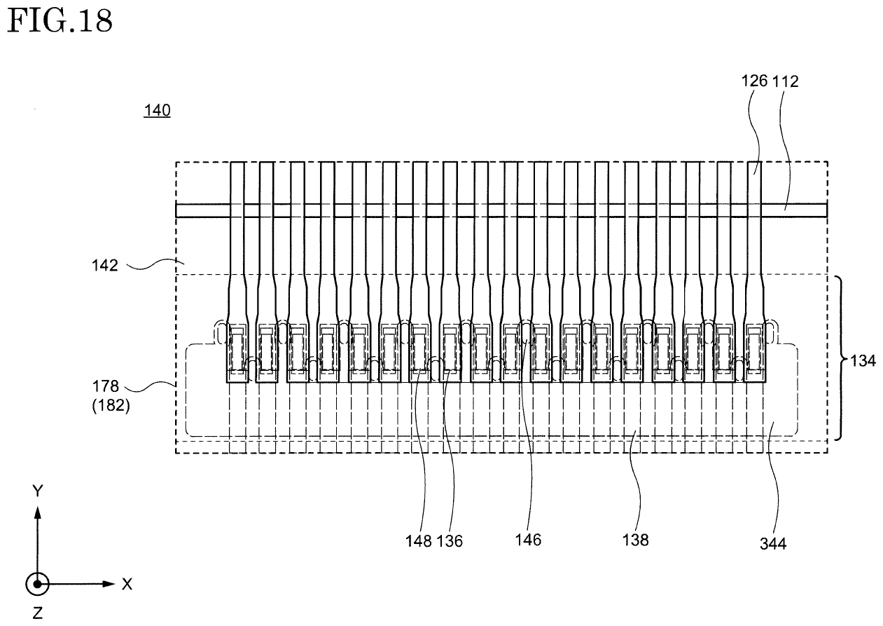

The insulating layer 146 is alternately arranged between the contact hole 136 on the first step portion 112 side and the substrate 102 end portion side. As shown in FIG. 16, the alternately arranged insulating layers 146 are located diagonally across the contact hole 136. As shown in FIG. 17, the insulating layer 146 is long in the longitudinal direction of the contact hole 136 and is arranged so as to sandwich the end portion close to the first step portion 112 of the contact hole 136. The insulating layer 146 is arranged diagonally across the contact hole 136. As shown in FIG. 18, in the case where the insulating layer 146 is long in the longitudinal direction of the contact hole 136, it may be arranged so that at least a portion of the contact hole 136 overlaps in the direction in which the sensor wiring 126 extends from the first step portion 112.

Embodiments including the modifications described above as embodiments of the present invention can be implemented in appropriate combinations as long as they do not contradict each other. Based on the embodiments including modifications, additions, deletions, or design changes of components, or additions, omissions, or conditional of processes by persons skilled in the art are also included in the scope of the present invention as long as it has the gist of the present invention.

In addition, even if there are other effects that are different from the effects brought about by the aspects of each embodiment described above, those that are clear from the description of this specification or those that can be easily predicted by the persons skilled in the art, it is naturally understood that it is brought about by the present invention.

What is claimed is:

1. A display device comprising:
a display region on a substrate;
a first step portion surrounding the display region in a plan view;
a first sensor electrode in the display region;
a first sensor wiring electrically connected with the first sensor electrode;
a first terminal electrode located between the display region and an edge of the substrate;
a first terminal wiring electrically connected to the first terminal electrode;
at least one contact hole located between the first step portion and the first terminal electrode;
at least one first insulating layer located around a periphery of the at least one contact hole;
a second insulating layer between the at least one first insulating layer and the substrate in a cross section; and
a third insulating layer over the first insulating layer and the second insulating layer,
wherein
the first sensor wiring and the first terminal wiring are electrically connected through the at least one contact hole,
the first sensor wiring is arranged over the first terminal wiring and the third insulating layer in a cross section,
the first sensor wiring includes a first edge and a second edge with different heights from the substrate over the third insulating layer,
the first edge is located on a part of the third insulating layer in contact with the at least first insulating layer, and
the second edge is located over a part of the third insulating layer in contact with the second insulation layer.

2. The display device according to claim 1, wherein the first edge and the second edge are located around the periphery of the contact hole in a plan view.

3. The display device according to claim 2, wherein
the at least one contact hole includes a plurality of contact holes,
the plurality of contact holes include a first contact hole and a second contact hole adjacent to each other, and
the at least one first insulating layer is located between the first contact hole and the second contact hole.

4. The display device according to claim 3, wherein the first edge located on a display region side of the first contact hole is closer to the display region than the second edge located on a display region side of the second contact hole.

5. The display device according to claim 1, wherein
the at least one first insulating layer includes a plurality of first insulating layers,
the at least one contact hole includes a plurality of the contact holes, and
the plurality of first insulating layers is located between the plurality of the contact holes respectively.

6. The display device according to claim 1, further comprising a second step portion surrounding the first step portion,
wherein
the at least one contact hole is located between the first step portion and the second step portion,
the first sensor wiring extends over the first step portion, and
the second step portion is located over the first terminal electrode.

7. The display device according to claim 1,
wherein
the third insulating layer comprises a first inorganic insulating layer and a second inorganic insulating layer, and
the second inorganic insulating layer is in contact with the first sensor wiring.
